(19) United States
(12) Patent Application Publication
(10) Pub. No.: US 2020/0343328 A1
(43) Pub. Date: Oct. 29, 2020

(54) DISPLAY PANEL

(71) Applicant: INT TECH CO., LTD., Hsinchu County (TW)

(72) Inventors: SHIN-SHIAN LEE, HSINCHU CITY (TW); YEN-CHIH CHIANG, HSINCHU COUNTY (TW)

(21) Appl. No.: 16/394,228

(22) Filed: Apr. 25, 2019

(51) Int. Cl. H01L 27/32; H01L 51/52; H01L 27/12

(52) U.S. Cl. CPC H01L 27/3276; H01L 51/5215; H01L 27/124; H01L 51/5234

(57) ABSTRACT

A display panel includes a substrate, an insulating layer, a light emitting device and a protecting layer. The substrate includes a light emitting region and a light transmitting region. The insulating layer is disposed over the substrate. The light emitting device is disposed in the light emitting region, wherein the light emitting device includes a first electrode over the substrate, a light emitting layer over the first electrode, and a second electrode over the light emitting layer. The second electrode is substantially vertically aligned with the light emitting device, and the light transmitting region is uncovered by the second electrode. The protecting layer covers the light emitting device and the insulating layer.

### TECHNICAL FIELD

The present disclosure is related to a display panel, especially to an organic light emitting display panel.

### BACKGROUND

Organic light emitting displays (OLED) are the technology of choice for augmented reality (AR) and virtual reality (VR) in transparent displays due to their advantages in latency, contrast ratio, response time, and black levels. However, due to the multilayer structure of the OLED displays, the transmittance of the OLED displays is low. In addition, the electrical resistance of the transparent electrodes in OLED displays is another impediment to exploiting the OLEDs in transparent displays. Therefore, the OLED industry is seeking routes to address the above issues.

### SUMMARY

A display panel includes a substrate, an insulating layer, a light emitting device and a protecting layer. The substrate includes a light emitting region and a light transmitting region. The insulating layer is disposed over the substrate. The light emitting device is disposed in the light emitting region, wherein the light emitting device includes a first electrode over the substrate, a light emitting layer over the first electrode, and a second electrode over the light emitting layer. The second electrode is substantially vertically aligned with the light emitting device, and the light transmitting region is uncovered by the second electrode. The protecting layer covers the light emitting device and the insulating layer.

In some embodiments, the first electrode includes an anode, and the second electrode includes a cathode. In some embodiments, the display panel includes a driving device over the substrate, and the driving device is electrically connected to the light emitting device. In some embodiments, the display panel further includes a transparent storage capacitor electrode disposed in the light transmitting region. In some embodiments, the protecting layer includes an extension portion disposed in the light transmitting region, wherein the extension portion extends toward the substrate and covers edges of the insulating layer. In some embodiments, the extension portion is in contact with the substrate.

In some embodiments, the display panel includes a light filter layer over the substrate. In some embodiments, the light filter layer includes a UV filter layer. In some embodiments, the display panel further includes a light absorbing layer disposed in the light emitting region and between the substrate and the light emitting device. In some embodiments, the display panel further includes a first light collimating component disposed in the light emitting region over the protecting layer. In some embodiments, the display panel further includes a second light collimating component disposed in the light transmitting region over the protecting layer. In some embodiments, the display panel further includes a plurality of light collimating components disposed over the protecting layer.

In some embodiments, the display panel includes a light guiding component disposed over the protecting layer, and the light emitting region is uncovered by the light guiding component. In some embodiments, the light guiding component is a porous film. In some embodiments, the display panel is embedded in a head mounted display device. In some embodiments, an area of the light transmitting region is substantially greater than an area of the light emitting region. In some embodiments, a ratio of the area of the light transmitting region to a total area of the substrate is substantially ranged from about 50% to about 80%. In some embodiments, the light transmitting region and the light emitting region are arranged in a staggered configuration. In some embodiments, the light transmitting region is configured for see-through viewing of an environment, and the light emitting region is configured to transmit light of a virtual image that is generated from the light emitting device. In some embodiments, the virtual image overlays on the environment

### BRIEF DESCRIPTION OF THE DRAWINGS

FIG. 1 represents an intermediate product of a display panel in accordance with some embodiments.

FIG. 2 represents an intermediate product of a display panel in accordance with some embodiments.

FIG. 3 represents an intermediate product of a display panel in accordance with some embodiments.

FIG. 4 represents an intermediate product of a display panel in accordance with some embodiments.

FIG. 5 illustrates a wearable display device in accordance with some embodiments.

FIG. 6 illustrates an enlarged view of part of the wearable display device in accordance with some embodiments.

FIG. 7 represents an intermediate product of a display panel in accordance with some embodiments.

FIG. 8 represents an intermediate product of a display panel in accordance with some embodiments.

FIG. 9 represents an intermediate product of a display panel in accordance with some embodiments.

### DETAILED DESCRIPTION OF THE DISCLOSURE

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of display panels are provided. The structure of the display panel may include a multilayer structure including at least two major levels. One level is configured as a light emitting level including an array of light emitting devices and provides luminescence for the panel. The light emitting devices can be made with organic or inorganic material. Another level is a circuit level which is electrically coupled to the light emitting level and vertically stacking with the light emitting level. The circuit level supplies power and control signals to the light emitting level in order to display the color or pattern as needed. In some embodiments, the arrangement of the light emitting devices in the array is determined through a photolithography operation.

An organic light emitting display panel is arranged with the light emitting device in each pixel and displays an image by individually controlling the light emission. The light emitting device includes a structure in which a light emitting layer including an organic material is sandwiched between a pair of electrodes regarded as an anode electrode and a cathode electrode. The organic light emitting display panel is arranged with one electrode as a pixel electrode in each pixel, and the other electrode as a common electrode which extends over a plurality of pixels and is applied with a common voltage. The organic light emitting display panel controls light emission from a pixel by applying the voltage of the pixel electrode to each pixel with respect to the voltage of the common electrode.

The organic light emitting display panels are the technology of choice for augmented reality and virtual reality in transparent displays due to their advantages in latency, contrast ratio, response time, and black levels. A transparent display is an electronic display that allows the user to see what is shown on the glass screen while still being able to see through it. These screens can be used for augmented reality, a way of enhancing your view of the world with digital images overlaid onto real ones, and other applications such as head-up displays, smart windows, and more sophisticated computer screens. However, the transparent displays have been notoriously difficult and expensive to produce.

The key limitation to transparent displays is in the multilayer structure of the OLED displays, which inherently limit the transmission efficiency for light. Generally, the transparent electrode is used as the common electrode in the OLED displays for obtaining a high transparency. However, the electrical resistance of the transparent electrode is significantly higher than that of a metal electrode. Consequently, the display panel including the transparent electrode is not suitable for mass production in terms of display quality and reliability.

As a result, improvements to the transparency and electrical resistance is vital to the success of transparent display technology. In the present disclosure, a display panel is provided to decrease the electrical resistance of the transparent electrode. The display panel decreases the expected electrical resistance of the transparent electrode by patterning the transparent electrode. In addition, the display panel of the present disclosure optimize the multilayer structure of the OLED display in the order to obtain a higher transparency.

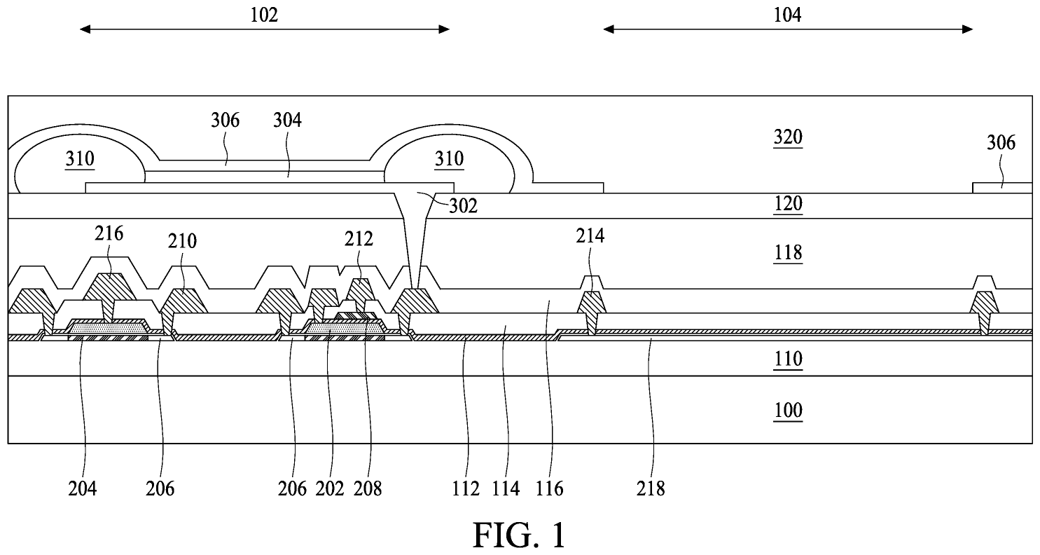

FIG. 1 represents an intermediate product of a display panel in accordance with some embodiments. A substrate 100 is provided in a display panel. The substrate 100 includes a light emitting region 102 and a light transmitting region 104. In some embodiments, an area of the light transmitting region 104 is substantially greater than an area of the light emitting region 102. In some embodiments, a ratio of the area of the light transmitting region 104 to a total area of the substrate 100 is substantially ranged from about 50% to about 80%. The substrate 100 is a transparent substrate, or at least a portion of the substrate 100 is transparent. The substrate 100 can include glass, quartz, or other suitable material. In some embodiments, the substrate 100 may be a transparent polyimide (PI) substrate. An insulating layer 110 is optionally disposed over the substrate 100 as shown in FIG. 1. In some embodiments, the insulating layer 110 may include dielectric materials. Specifically, the insulating layer 110 may be made with silicon oxide, silicon nitride, silicon oxynitride, or other suitable materials.

A circuit tier is disposed over the substrate 100. The circuit tier may have several transistors and capacitor. Each transistor may have a gate electrode 202 over a channel 204. The gate electrode 202 can be made with conductive material such as metal, or silicide. In some embodiments, the gate electrode 202 can be a composite structure including several different layers and the different layers may be distinguishable after applying etchant and observed under microscope. The channel 204 may be made with semiconductive material such as silicon, or other element selected from group IV, or group III and V. In the transistor, the insulating layer 110 is between the gate electrode 202 and the channel 204. The source/drain electrodes 206 are disposed on opposite side of the channel 204 to provide carriers. In some embodiments, the transistors is disposed in the light emitting region 102 only, and the light transmitting region 104 is uncovered by the transistors.

Conductive features are formed to connect with the transistors and capacitor. Conductive features may include some conductive vias 210, which are connected to the source/drain electrodes 206 of the transistor at one end. Conductive features may include some conductive vias 212, which are connected to the gate electrode 202 of the transistor or a capacitor metal 208 at one end. Conductive features may include some conductive vias 214, which are connected to a lower electrode 218 of the capacitor at one end. Conductive features may include some conductive traces 216, which are configured as interconnect between different transistors or other electronic component in the circuit tier.

A dielectric layer 114 is disposed between the transistors and the conductive traces 216. In some embodiments, the dielectric layer 114 may include more than one layer as shown in FIG. 1. Conductive vias 210, 212, and 214 respectively penetrate through the dielectric layer 114. The dielectric layer 114 is conformal to the topography of the transistors and capacitor disposed over substrate 100. Therefore, a top surface of a dielectric layer 112 can be up and down and follows the topography of the transistors and capacitor under the dielectric layer 114.

Total height of each conductive via may be different because the penetration depth of each conductive via is determined by the total thickness of the dielectric layer 114 and the other films under the dielectric layer 114. For example, the conductive via 212 connected to the capacitor metal 208 has a shorter total height than the conductive via 212 connected to the gate electrode 202 because the conductive via 212 connected to the gate electrode 202 needs to further penetrate through the dielectric layer 112, which is between the gate electrode 202 and the capacitor metal 208. Similarly, conductive via 212 connected to the gate electrode 202 has a shorter total height than conductive via 210 connected to source/drain electrodes 206.

Another dielectric layer 116 is disposed to cover the conductive traces 216. In some embodiments, the dielectric layer 116 includes silicon nitride in order to be more resistant to moisture and acid than the dielectric layer 114. In some embodiments, the dielectric layer 116 is conformal to the conductive vias 210, the conductive vias 212, the conductive vias 214 and the conductive traces 216 in order to provide better protection to the conductive traces 216. Therefore, similar to the dielectric layer 114, a top surface of the dielectric layer 116 can be up and down and follows the topography of the conductive vias 210, the conductive vias 212, the conductive vias 214 and the conductive traces 216 thereunder.

A planarization layer 118 is optionally disposed over the top surface of the dielectric layer 116. Compared to the dielectric layers 116 and 114, the planarization layer 118 has a higher capability to gap filling. Therefore, if there is any recess on the top surface of the dielectric layer 116, the planarization layer 118 fills the recess to minimize the roughness of the top surface of the dielectric layer 116. Further, the planarization layer 118 also provides a flat surface for proceeding operations. The planarization layer 118 can be formed by various methods including vapor deposition, jetting, spin coating, atomic layer deposition. In some embodiments, the planarization layer 118 is also a dielectric layer and can be made with an organic or an inorganic material. In some embodiments, the planarization layer 118 is a spin on glass (SOG) containing inorganic material such as silicon oxide or silicon oxynitride. The planarization layer 118 may have a thickness between about 400 nm and about 700 nm.

Another dielectric layer 120 is optionally disposed over the planarization layer 118 as shown in FIG. 1. The dielectric layer 120 is selected from a material different from the planarization layer 118. One of the reasons to use different materials between the dielectric layer 120 and the planarization layer 118 is to increase the selectivity between the dielectric layer 120 and the planarization layer 118 for some proceeding etch operations. In some embodiment, the dielectric layer 120 is made with inorganic material and the planarization layer 118 is made with organic material. The dielectric layer 120 may be made with silicon oxide, silicon nitride, silicon oxynitride, or other suitable materials. The dielectric layer 120 can be optionally blanket disposed on the planarization layer 118. In some embodiments, the planarization layer 118 is made with inorganic material and there is no extra dielectric layer 120 needed.

A first electrode 302 is disposed on the dielectric layer 120. In addition, the first electrode 302 includes an extension portion extending toward the conductive via 210 and penetrating through the dielectric layer 120, the planarization layer 118 and the dielectric layer 116. The first electrode 302 may include conductive materials. For example, the conductive materials can be metal such as Al, Cu, Ag, Au, W, etc. or metal alloy. In some embodiments, the conductive materials can be transparent metal oxide such as indium tin oxide (ITO), indium zinc oxide (IZO), aluminum-doped zinc oxide (AZO) and indium-doped cadmium oxide, etc. In some embodiments, the first electrode 302 may be, but not limited to be, in direct contact with the dielectric layer 120. The first electrode 302 is prepared for the light emitting device to electrically communicating with the circuit tier. In some embodiments, the first electrode 302 is designed as an anode of the light emitting device.

A pixel defining layer including a plurality of spacers 310 is formed on the substrate 100 and separates the light emitting devices from one another when viewed in a thickness direction of the display panel. The spacers 310 can be optionally disposed over the dielectric layer 120 as shown in FIG. 1. In some embodiments, the spacers 310 partially cover the first electrode 302 and leave a portion of the first electrode 302 open to receive the light emitting materials. In some embodiments, the spacers 310 include polymeric material. In some embodiments, the spacers 310 include photosensitive material. In some embodiments, the spacers 310 are photo absorption material. In some embodiments, the spacers 310 are fluorine free, i.e. substantially contains no fluorine. In some embodiments, the spacers 310 are formed through a photolithography operation.

A light emitting device is disposed in the light emitting region 102 of the substrate 100. The light emitting device includes the first electrode 302 over the substrate 100, a light emitting layer 304 over the first electrode 302 and a second electrode 306 over the light emitting layer 304. The light emitting layer 304 is disposed on the first electrode 302 as shown in FIG. 1. In some embodiments, the light emitting device is an organic light emitting device. The light emitting layer 304 may have several sublayers stacked over the first electrode 302. Specifically, the light emitting layer 304 may include a first carrier injection sublayer, a first carrier transportation sublayer, a light emitting sublayer, a second carrier transportation sublayer and a second carrier injection sublayer. In some embodiments, the first carrier injection layer is for hole injection. In some embodiments, the first carrier injection layer is for electron injection.

The second electrode 306 is formed over the light emitting layer 304. In addition, the second electrode 306 is substantially vertically aligned with the light emitting device, and the light transmitting region 104 is uncovered by the second electrode 306. In other words, the second electrode 306 is a patterned electrode and a surface of the dielectric layer 120 is uncovered by the second electrode. In some embodiments, the second electrode 306 is designed as a cathode of the light emitting device. The second electrode 306 partially overlaps the lower electrode 218 of the capacitor in the peripheral region near the light transmitting region 104 when viewed in a thickness direction of the display panel. In some embodiments, the second electrode 306 may be designed as an upper electrode of the capacitor. In addition, the second electrode 306 can be the cathode of the light emitting device and the upper electrode of the capacitor at the same time.

The capacitor disposed on the insulating layer 110 may have the lower electrode 218 and an upper electrode (i.e. the second electrode 306). The capacitor extends over the light transmitting region 104 in the display panel according to the present embodiment. The capacitor in the present embodiment has a structure in which the planarization layer 118 and the dielectric layers 112, 114, 116 and 120 are sandwiched by the upper electrode and the lower electrode 218. Since the lower electrode 218 allows light to pass through, it is preferred that the lower electrode 218 is transparent and is formed from a transparent thin film such as ITO (indium doped with tin oxide) or IZO (Indium zinc oxide) having conductive properties. Alternatively, the lower electrode 218 may also be formed using a metal film formed to a thickness that allows light to pass through. In some embodiments, the capacitor may be a storage capacitor.

In the present disclosure, the display panel may be provided including a plurality of pixels, and the plurality of pixels is arranged in a matrix form. Each pixel has a light emitting region 102 and a light transmitting region 104. The light emitting region 102 has a light emitting device. The light transmitting region 104 is covered with the lower electrode of the capacitor. The upper electrode of the capacitor may be the second electrode 306. The second electrode 306 is a patterned conductive layer disposed continuously in the plurality of pixels. In other words, the upper electrodes of the capacitor disposed in each pixel are connected. The second electrode 306 may include a plurality of openings arranged in a matrix, and each opening exposes a surface of the dielectric layer 120. In addition, each opening is substantially vertically aligned with the light transmitting region 104.

The second electrode 306 may include conductive materials. In some embodiments, the second electrodes 108 may be provided as a transmissive electrode. For example, the second electrodes 108 may be formed by a thin transmissive layer which is made of metal oxides. Examples of the transparent conductive material may include indium tin oxide (ITO), indium zinc oxide (IZO), aluminum-doped zinc oxide (AZO) and indium-doped cadmium oxide, etc. In some embodiments, the second electrode 306 may be provided as a transflective electrode. For example, the second electrode 304 may be formed by a thin transflective layer which is made of metal having a low work function, that is, alkali metal such as lithium (Li) and cesium (Cs), alkaline earth metal such as magnesium (Mg), calcium (Ca) and strontium (Sr), and compounds thereof. A transparent conductive layer made of indium tin oxide (ITO) and indium zinc oxide (MO) may be further included above or below the metal transflective layer.

A protecting layer 320 covering the light emitting device and the insulating layer 110 is disposed on the substrate 100. The protecting layer 320 for protecting the light emitting layer 304 from an external environment such as moisture or oxygen may be provided on the second electrodes 306. The protecting layer 320 may be formed of a thin film encapsulation layer in which a plurality of organic layers and inorganic layers cross each other and are laminated or a transparent substrate such as encap glass. In some embodiments, the protecting layer 320 may include a plurality of organic layers and a plurality of inorganic layers which are alternately laminated. The organic layers may be formed by containing acrylate-based materials and the inorganic layers may be formed by containing oxide-based materials.

The expected transparency of the display panel of the present disclosure may be increased by adopting various approaches. The lower electrode 218 of the capacitor and the second electrode 306 may be transparent electrodes. In other words, one of the approaches is to use transparent conductive materials in the electrodes. Since the lower electrode 218 of the capacitor and the second electrode 306 are transparent, the expected transparency of the display panel 306 is elevated. Another exemplary approach is to change the shape of the second electrode 306. As shown in FIG. 1, the second electrode 306 is patterned and the light transmitting region 104 is uncovered by the second electrode 306. Consequently, the amount of layers disposed in the light transmitting region 104 on the substrate 100 is reduced. Therefore, the transparency of the display panel may be increased due to the uncovered area of the second electrode 306 in the light transmitting region 104.

The expected electrical resistance of the second electrode 306 of the present disclosure may be decreased by adopting various approaches. As shown in FIG. 1, the light transmitting region 104 is uncovered by the second electrode 306. The second electrode may be a transparent electrode. In other words, one of the approaches is to pattern the second electrode 306. For a given material, the electrical resistance is proportional to the length and is inversely proportional to the cross-sectional area. Since the second electrode 306 is patterned, the length of the second electrode 306 is reduced. Consequently, the expected electrical resistance of the second electrode 306 is decreased. Another exemplary approach is to change the material of the second electrode 306. Since the second electrode 306 is patterned, the second electrode 306 may no longer be the transparent electrode. The second electrode 306 may be a metal electrode. Therefore, the expected electrical resistance of the second electrode 306 may be further decreased.

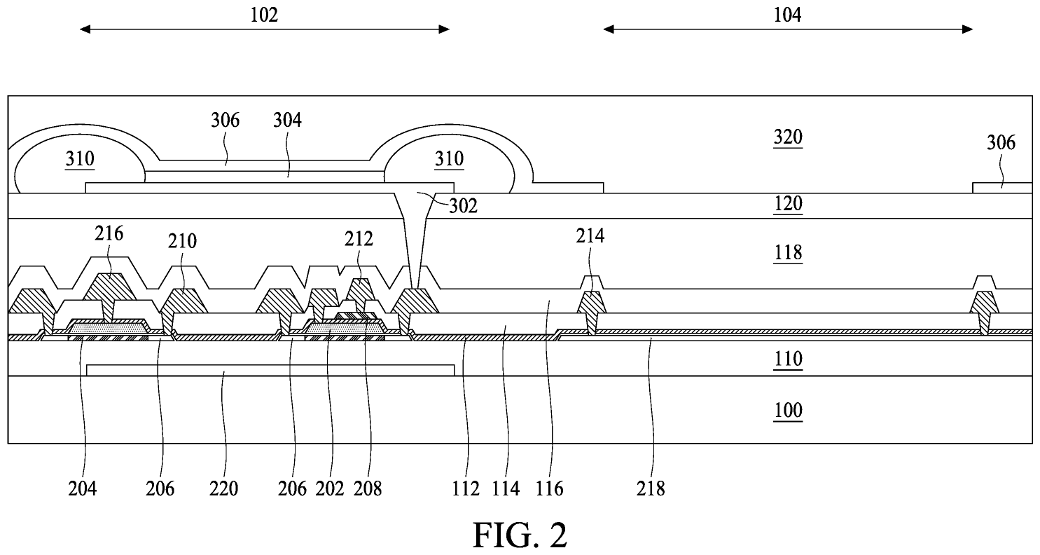

Other alternatives or embodiments may present without departure from the spirit and scope of the present disclosure. FIG. 2 represents an intermediate product of a display panel in accordance with some embodiments. Different from FIG. 1, the display panel further includes a light absorbing layer 220 disposed in the light emitting region 102 and between the substrate 100 and the light emitting device. In some embodiments, the light absorbing layer 220 may be made with black material, which absorbs visible lights substantially. Specifically, the light absorbing layer 220 may absorbs the light emitted from the light emitting device.

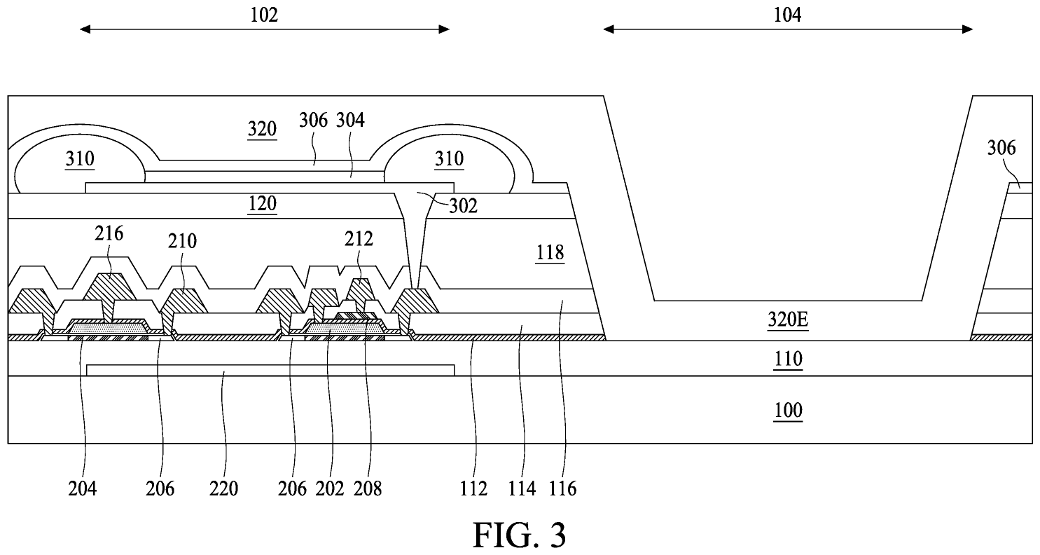

FIG. 3 represents an intermediate product of a display panel in accordance with some embodiments. Different from FIG. 2, the protecting layer 320 includes an extension portion 320E disposed in the light transmitting region 104, wherein the extension portion 320E extends toward the substrate 100 and covers edges of the insulating layer 110 and the dielectric layers 120, 118, 116, 114 and 112. In other words, most layers in the light transmitting region 104 are patterned. Specifically, the dielectric layers 120, 118, 116, 114 and 112 are patterned, and the light transmitting region 104 is uncovered by the dielectric layers 120, 118, 116, 114 and 112. Since the multilayer structure in the light transmitting region 104 is significantly reduced to a double layer structure, a higher transparency may be obtained. In some embodiments, the extension portion 320E may be in contact with the substrate 100. Therefore, a much higher transparency is expected.

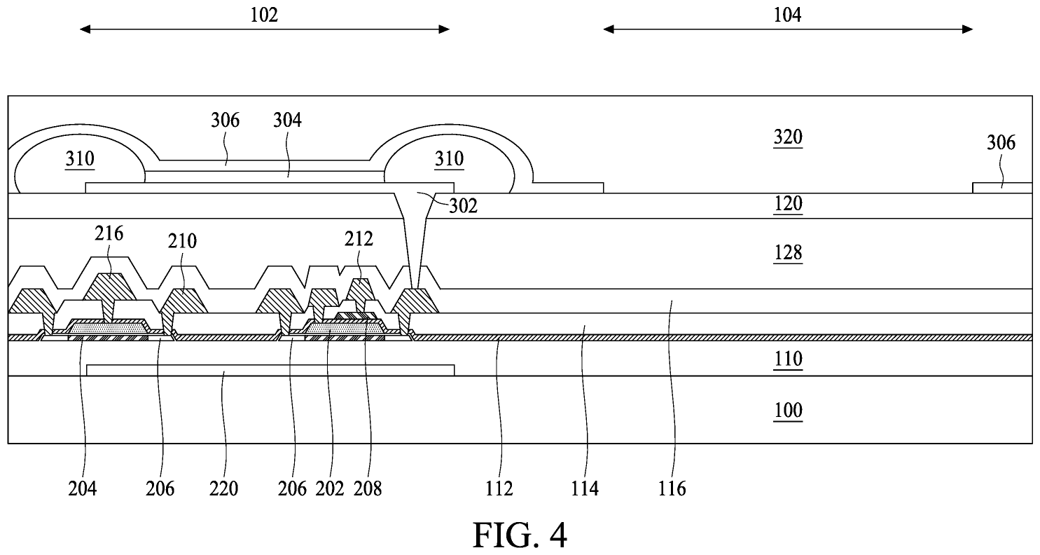

FIG. 4 represents an intermediate product of a display panel in accordance with some embodiments. Different from FIG. 2, the display panel further includes a light filter layer 128 over the substrate 110. In some embodiments, the light filter layer 128 includes a UV filter layer, which absorbs UV lights substantially. In the present disclosure, the planarization layer 118 may be replaced by the light filter layer 128 as shown in FIG. 4. Since OLEDs are sensitive to UV light, the presence of the light filter 128 is essential. Otherwise the OLEDs will be damaged after being exposed to UV light in a short time.

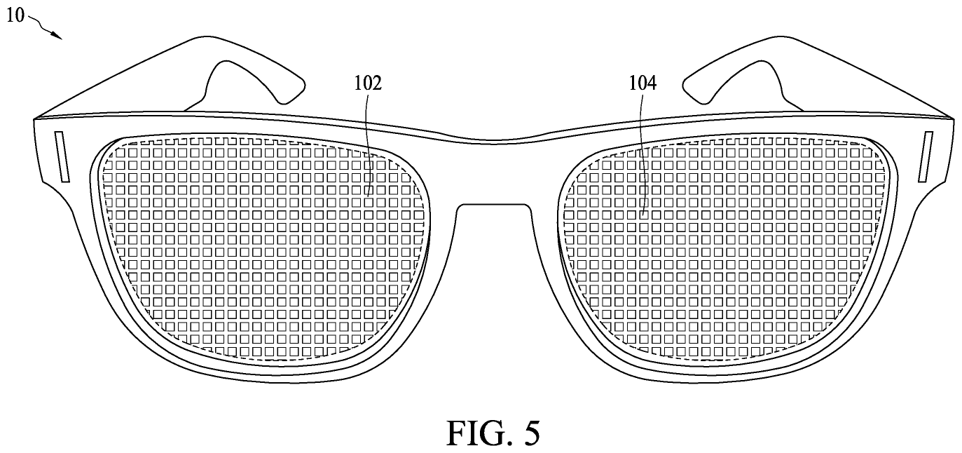

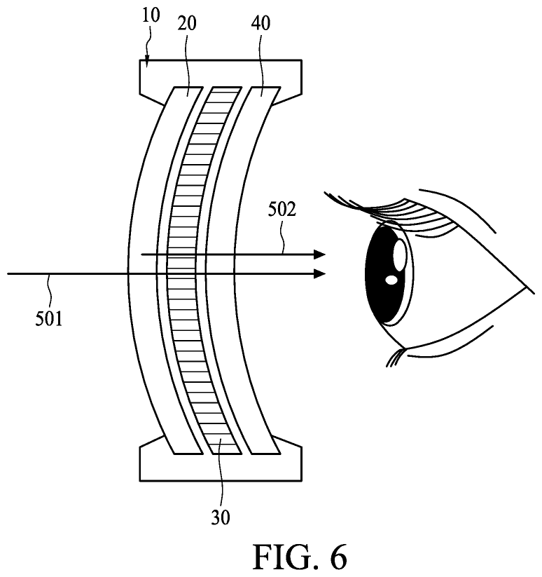

Please refer to FIG. 5 and FIG. 6. FIG. 5 illustrates a wearable display device in accordance with some embodiments, and FIG. 6 illustrates an enlarged view of part of the wearable display device in accordance with some embodiments. As shown in FIGS. 5-6, the display panel 20 illustrated in FIG. 6 may be embedded in the wearable display device. In some embodiments, the display panel 20 is embedded in a head mounted display device 10 as shown in FIG. 6. In the present embodiment, the head mounted display device 10 illustrated in FIGS. 5-6 is eyeglasses. The eyeglasses may include a pair of lenses 40. The arrangement of each layer of the display panel 20 can be referred to the aforementioned description and the embodiments illustrated in FIGS. 1-4, and the embodiments and the drawings should not be deemed as limitation.

As shown in FIG. 5, the display panel 20 of the head mounted display device 10 includes a light emitting region 102 and a light transmitting region 104. The light emitting devices may be disposed only in the light emitting region 102, and the light transmitting region 104 may be free of the light emitting devices. In some embodiments, the light transmitting region 104 and the light emitting region 102 may be arranged in a staggered configuration. In some embodiments, the light transmitting region 104 and the light emitting region 102 may be arranged in a mesh configuration. The arrangement of the light transmitting region 104 and the light emitting region 102 may have other configurations. For example, the light emitting region 102 may be placed at one of the corners of the substrate 110, such as the upper left corner, the upper right corner, the lower left corner, or the lower right corner. Alternatively, the light emitting region 102 may be placed on the upper half, the lower half, the left half, or the right half of the substrate 110.

Moreover, the light transmitting region 104 may be configured for see-through viewing of an environment, and the light emitting region 102 may be configured to transmit light of a virtual image that is generated from the light emitting device. In other words, the light emitting devices are driven to display a virtual image in the light emitting region 102. The light transmitting region 104 remains transparent because the light emitting device is not disposed therein. When the user wears the head mounted display device 10, the user may see the virtual image overlays on the environment. Specifically, the user views reality directly through optical elements such as collimator as will be discussed below and other systems that enable graphical overlay on the real world.

Please refer to FIG. 6, the head mounted display device 10 may include the display panel 20 and the lens 40. In some embodiments, the display panel 20 may further include the collimator 30. The collimator 30 may magnify the image generated by the display panel 20 and injects it into the lens 40. The collimator 30 may project collimated light such that the image appears at a greater distance than its physical distance. Furthermore, light collimation can be used to selectively block and/or direct beams of light in order to create virtual objects in a person's field of vision. The lens 40 can be selected from the group including: aspheric lens, asymmetric lens, compound lens, concave lens, concentric lenses, convex lens, curved lens, filtered lens, flat lens, simple lens, smart lens, spherical lens, virtual curved lens, and vision-correcting lens.

As shown in FIG. 6, the light beam 501 represents the light rays from the real world, and the light beam 502 represents the artificial light rays generated by the light emitting devices to form a digital world. The head mounted device 10 combines the generated image with the real world, and thus the user's eye may see the virtual image overlays on the environment.

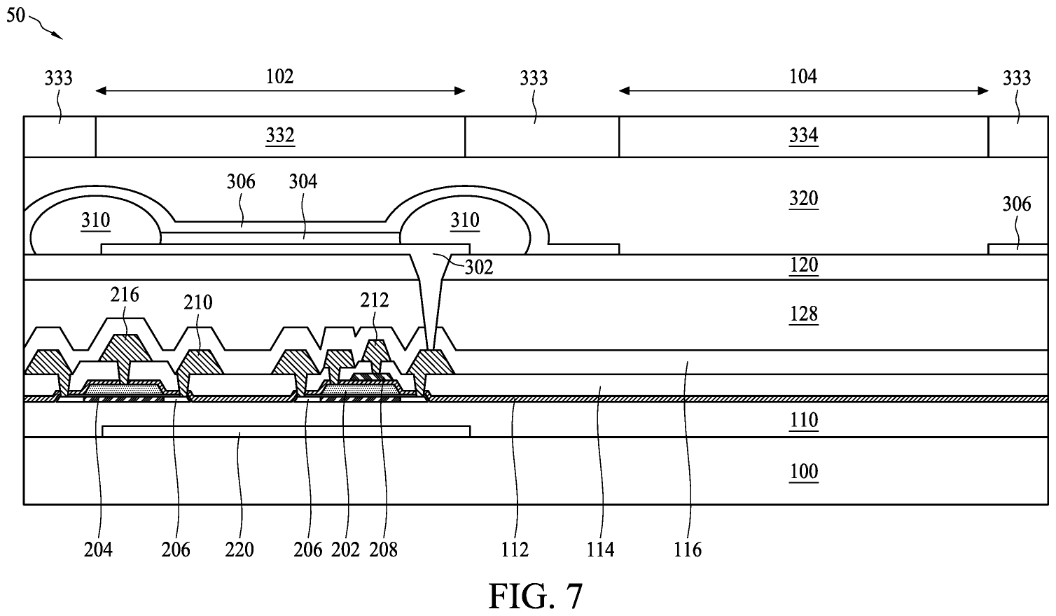

FIG. 7 represents an intermediate product of a display panel in accordance with some embodiments. Different from FIG. 4, the display panel 50 further includes a first light collimating component 332 disposed in the light emitting region 102 over the protecting layer 320. In some embodiments, the display panel 50 may further include a second light collimating component 334 disposed in the light transmitting region 104 over the protecting layer 320. Another protecting layer 333 is optionally disposed over the protecting layer 320 and is disposed between the first light collimating component 332 and the second light collimating component 334 as shown in FIG. 7. The first light collimating component 332 and the second light collimating component 334 may be a collimator lens or a collimation prism film, and is used to collimate wide divergent light from the light emitting device into a small cone angle light. Accordingly, the display panel 50 of the present disclosure may be a suitable display panel for near-eye virtual and augmented reality devices.

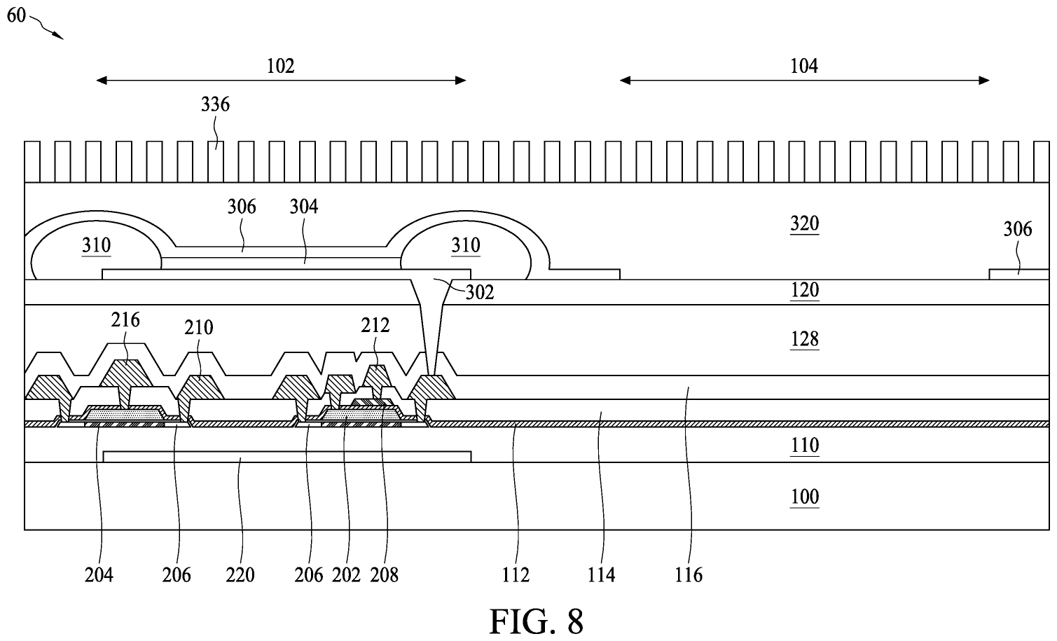

FIG. 8 represents an intermediate product of a display panel in accordance with some embodiments. Different from FIG. 4, the display panel 60 further includes a plurality of light collimating components 336 over the protecting layer 320. The light collimating components 336 are disposed evenly over the light transmitting region 104 and the light emitting region 102. The light collimating components 336 may be a micro-structure lenses array. The light collimating components 336 may be used to selectively block and/or direct beams of light in order to create virtual objects in a person's field of vision. Accordingly, the display panel 60 of the present disclosure may be a suitable display panel for near-eye virtual and augmented reality devices.

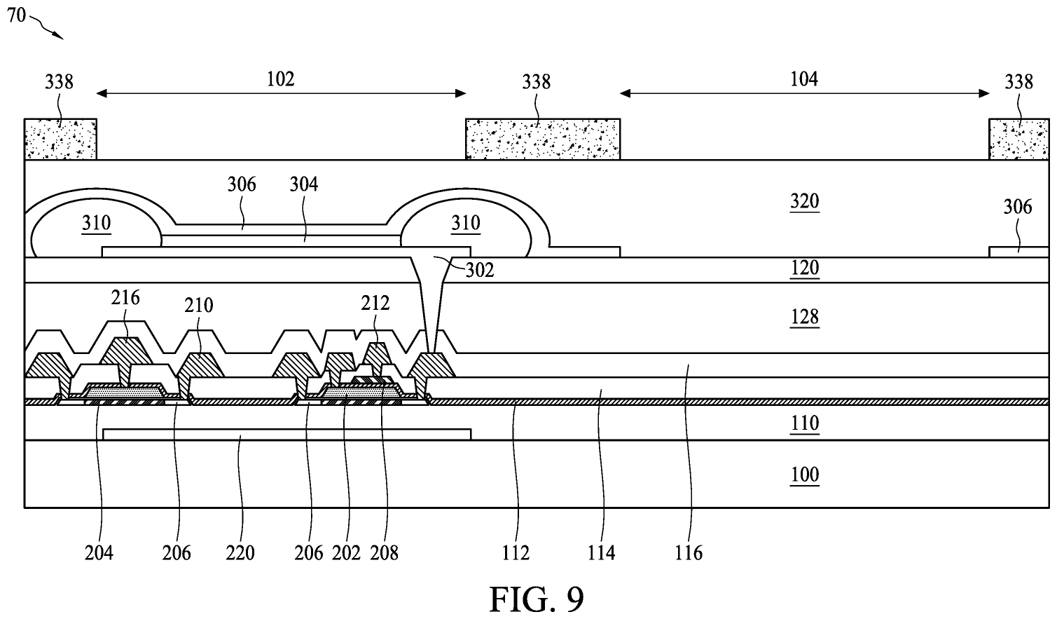

FIG. 9 represents an intermediate product of a display panel in accordance with some embodiments. Different from FIG. 4, the display panel 70 further includes a light guiding component 338 over the protecting layer 320. In some embodiments, the light emitting region 102 is uncovered by the light guiding component 338 and the rest area other than the light emitting region 102 is covered by the light guiding component 338 when viewed in a thickness direction of the display panel 70. In some embodiments, both the light emitting region 102 and the light transmitting region 104 are uncovered by the light guiding component 338. The light guiding component 338 may cover the boundaries between the light emitting region 102 and the light transmitting region 104. The light guiding component 338 may be a porous film, a membrane with porous structure or a thin film including millions of channels, bubbles or nanoparticles arranged randomly, and is used for refracting, reflecting or shielding the divergent light. The light guiding component 338 may help collimate the image generated by the display panel 70 by guiding the divergent light. Consequently, the display panel 70 may be a suitable display panel for near-eye virtual and augmented reality devices.

Please note that the arrangement of each layer of the display panels 50, 60 and 70 can be referred to the aforementioned description and the embodiments as illustrated in FIGS. 1-4, and the embodiments and the drawings should not be deemed as limitation.

In the present disclosure, several embodiments of a display panel are provided to increase the transparency and decrease the electrical resistance of the transparent electrode in OLED displays. The display panel decreases the electrical resistance of OLEDs by patterning the cathode electrode. In addition, the display panels of the present disclosure reduce the amount of dielectric/insulating layers in the light transmitting region in order to obtain a higher transparency.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A display panel, comprising:
a substrate comprising a light emitting region and a light transmitting region;
an insulating layer over the substrate;
a light emitting device disposed in the light emitting region, wherein the light emitting device comprises:
a first electrode over the substrate;
a light emitting layer over the first electrode; and
a second electrode over the light emitting layer, wherein the second electrode is substantially vertically aligned with the light emitting device, and the light transmitting region is uncovered by the second electrode; and
a protecting layer covering the light emitting device and the insulating layer.

2. The display panel in claim 1, wherein the first electrode comprises an anode, and the second electrode comprises a cathode.

3. The display panel in claim 1, further comprising a driving device over the substrate, and electrically connected to the light emitting device.

4. The display panel in claim 1, further comprising a transparent storage capacitor electrode disposed in the light transmitting region.

5. The display panel in claim 1, wherein the protecting layer includes an extension portion disposed in the light transmitting region, wherein the extension portion extends toward the substrate and covers edges of the insulating layer.

6. The display panel in claim 5, wherein the extension portion is in contact with the substrate.

7. The display panel in claim 1, further comprising a light filter layer over the substrate.

8. The display panel in claim 7, wherein the light filter layer comprises a UV filter layer.

9. The display panel in claim 1, further comprising a light absorbing layer disposed in the light emitting region and between the substrate and the light emitting device.

10. The display panel in claim 1, further comprising a first light collimating component disposed in the light emitting region over the protecting layer.

11. The display panel in claim 10, further comprising a second light collimating component disposed in the light transmitting region over the protecting layer.

12. The display panel in claim 1, further comprising a plurality of light collimating components disposed over the protecting layer.

13. The display panel in claim 1, further comprising a light guiding component disposed over the protecting layer, and the light emitting region is uncovered by the light guiding component.

14. The display panel in claim 13, wherein the light guiding component is a porous film.

15. The display panel in claim 1, wherein the display panel is embedded in a head mounted display device.

16. The display panel in claim 15, wherein an area of the light transmitting region is substantially greater than an area of the light emitting region.

17. The display panel in claim 15, wherein a ratio of the area of the light transmitting region to a total area of the substrate is substantially ranged from about 50% to about 80%.

18. The display panel in claim 15, wherein the light transmitting region and the light emitting region are arranged in a staggered configuration.

19. The display panel in claim 15, wherein the light transmitting region is configured for see-through viewing of an environment, and the light emitting region is configured to transmit light of a virtual image that is generated from the light emitting device.

20. The display panel in claim 19, wherein the virtual image overlays on the environment.
